(19) United States
(12) Patent Application Publication
(10) Pub. No.: US 2011/0248737 A1
(43) Pub. Date: Oct. 13, 2011

(54) TEST APPARATUS AND CONNECTION DEVICE

(75) Inventors: Satoshi TAKESHITA, Saitama (JP); Junji EBARA, Saitama (JP); Tomoyuki TAKAMOTO, Gunma (JP); Koei NISHIURA, Saitama (JP); Hidehiko YASUNO, Gunma (JP)

(73) Assignee: ADVANTEST CORPORATION, Tokyo (JP)

(21) Appl. No.: 13/034,625

(22) Filed: Feb. 24, 2011

(30) Foreign Application Priority Data
Apr. 13, 2010 (JP) 2010-092208

(51) Int. Cl. G01R 31/00

(52) U.S. Cl. 324/756.02

(57) ABSTRACT

It is an object to use an additional circuit to increase speed and functioning of an existing test apparatus at a low cost. Provided is a test apparatus that is connected to a socket board corresponding to a type of device under test and tests the device under test. The test apparatus comprises a test head including therein a test module that tests the device under test; a function board that is connected to the test module in the test head via a cable and also connected to the socket board; and an additional circuit that is loaded on the function board and connected to the test module and the device under test.

### BACKGROUND

1. Technical Field

The present invention relates to a test apparatus and a connection apparatus.

2. Related Art

A test apparatus is known that tests a semiconductor device, as in Patent Document 1, for example. A manufacturer of semiconductor devices must continue developing new test apparatuses to keep up with the higher speeds and functioning of the devices. Implementing a new test apparatus, however, increases the cost of the devices and decreases the operating efficiency of test apparatuses already in use.
Patent Document 1: Japanese Patent Application Publication No. 2008-292488

There are cases where the board of an existing test apparatus on which devices under test are loaded is provided with an additional circuit, thereby enabling the test apparatus to test devices with higher speeds and functioning. As a result, there is less need to implement new test apparatuses and the operating efficiency of existing test apparatuses can be improved.

This technique increases manufacturing cost since the additional circuit is a circuit for testing devices with higher speeds and functioning. Furthermore, the boards on which the devices under test are placed differ depending on the type of device under test. Accordingly, a different additional circuit must be created for each board on which a device under test is provided, thereby increasing the cost.

In addition, when an additional circuit is disposed on a board, the area in which devices under test can be provided is decreased. Accordingly, when an additional circuit is disposed on a board on which devices under test are placed, the number of devices under test that can be tested in parallel is decreased.

Furthermore, a board on which devices under test are placed experiences a force when a handler attaches or detaches the devices under test. When performing a quick reliability test or the like, a board on which devices under test are placed is sealed in a chamber and heated along with the devices under test. Accordingly, an additional circuit disposed on a board on which devices under test are placed is prone to mechanical stress and thermal stress during testing.

### SUMMARY

Therefore, it is an object of an aspect of the innovations herein to provide a test apparatus and a connection apparatus, which are capable of overcoming the above drawbacks accompanying the related art. The above and other objects can be achieved by combinations described in the independent claims. According to a first aspect related to the innovations herein, provided is a test apparatus that is connected to a socket board corresponding to a type of device under test and tests the device under test. The test apparatus comprises a test head including therein a test module that tests the device under test; a function board that is connected to the test module in the test head via a cable and also connected to the socket board; and an additional circuit that is loaded on the function board and connected to the test module and the device under test. Also provided is a connection apparatus used by the test apparatus.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a test apparatus 10 according to an embodiment of the present invention, along with devices under test 200.

FIG. 2 shows a configuration of the connection apparatus 14 according to the present embodiment, along with a device under test 200 and the test head 12.

FIG. 3 shows an exemplary mechanical configuration of the connection apparatus 14 according to the present embodiment, along with devices under test 200.

FIG. 4 shows an exemplary mechanical structure of the connection apparatus 14 according to the present embodiment, along with a line indicating a portion that is exchanged together with replaceable parts of the device under test 200.

FIG. 5 shows a partial structure of the connection apparatus 14 according to the present embodiment.

FIG. 6 shows an exemplary component for injecting or expelling cooling gas according to the present embodiment.

FIG. 7 shows an exemplary connection of a component for injecting or expelling cooling gas according to the present embodiment.

FIG. 8 shows an exemplary bottom surface of the function board 50, i.e. the surface facing the test head 12, according to the present embodiment.

FIG. 9 shows an exemplary arrangement of connection units 28 and devices under test 200 connected to the socket board 34, according to the present embodiment.

FIG. 10 shows an exemplary connection unit 28 and connection unit frame 40 according to the present embodiment.

FIG. 11 shows an exemplary internal configuration of a connection unit 28 according to the present embodiment.

FIG. 12 shows an exemplary connection of the function board 50, the connection unit 28, and the connection unit frame 40 in the function board frame 60 according to the present embodiment.

FIG. 13 shows an exemplary connection of the function board 50, the connection unit frame 40, the side wall 42, the socket board 34, and the socket frame 38 in the function board frame 60 according to the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

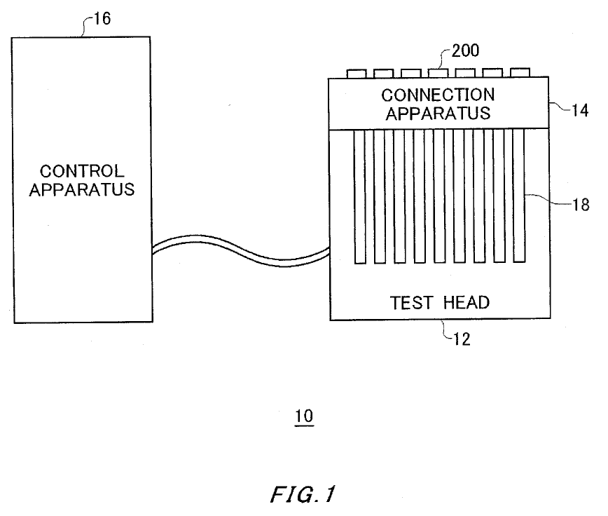

FIG. 1 shows a configuration of a test apparatus 10 according to an embodiment of the present invention, along with devices under test 200. The test apparatus 10 of the present embodiment tests at least one device under test 200.

The test apparatus 10 includes a test head 12, a connection apparatus 14, and a control apparatus 16. The test head 12 includes at least one test module 18 therein for testing the device under test 200. Each test module 18 exchanges signals with the corresponding device under test 200 to test this device under test 200.

The connection apparatus 14 is disposed on the test head 12. The devices under test 200 are disposed on the top surface of the connection apparatus 14, i.e. the surface that is opposite the surface connected to the test head 12. The devices under test 200 can be attached to or detached from the connection apparatus 14 by a handler. The connection apparatus 14 provides an electrical connection between a terminal of each test module 18 and a terminal of the corresponding device under test 200.

The control apparatus 16 may be a computer executing a program, for example, for controlling the overall test apparatus 10. The control apparatus 16 controls each test module 18 by communicating with the test module 18 in the test head 12 according to the program.

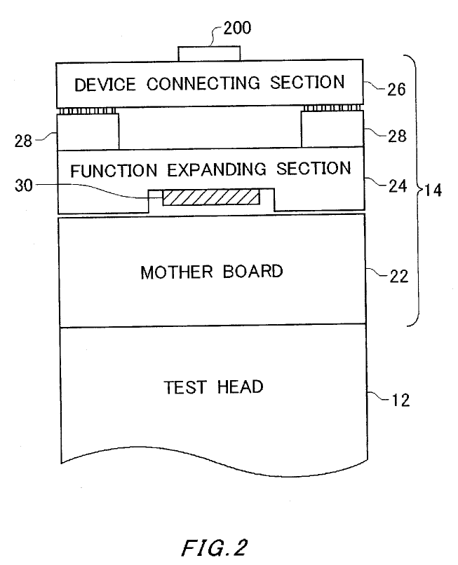

FIG. 2 shows a configuration of the connection apparatus 14 according to the present embodiment, along with a device under test 200 and the test head 12. The connection apparatus 14 includes a motherboard 22, a function expanding section 24, and a device connecting section 26.

The motherboard 22 is disposed on the test head 12. The motherboard 22 houses a signal cable, which provides a connection between the function expanding section 24 and the test module 18 in the test head 12, and a power supply cable, which provides a connection between the function expanding section 24 and a power supply apparatus, for example.

The function expanding section 24 is disposed on top of the motherboard 22. In other words, the function expanding section 24 is connected to the surface of the motherboard 22 that is opposite the surface connected to the test head 12. The function expanding section 24 includes a connector on the motherboard 22 side surface thereof, i.e. the surface facing the test head 12. The connector is connected to the power supply cable, which is connected to the power supply apparatus, and the signal cable, which is connected to the test module 18, housed in the motherboard 22.

The device connecting section 26 is disposed on top of the function expanding section 24. In other words, the device connecting section 26 is connected to a surface of the function expanding section 24 that is opposite the surface connected to the motherboard 22, i.e. opposite the surface of the function expanding section 24 facing the test head 12. The device under test 200 is loaded on the top surface of the device connecting section 26, i.e. the surface facing away from the test head 12. The device connecting section 26 provides an electrical connection between the function expanding section 24 and the device under test 200 loaded thereon.

The function expanding section 24 includes a plurality of connection units 28 and an additional circuit 30. The additional circuit 30 is disposed on the motherboard 22 side surface of the function expanding section 24, i.e. the surface facing the test head 12.

The additional circuit 30 is electrically connected to the device under test 200 and the test module 18 in the test head 12. The additional circuit 30 is an integrated circuit device that is controlled by the test module 18 in the test head 12 to test the device under test 200. The additional circuit 30 may be an FPGA (Field Programmable Gate Array). The additional circuit 30 may be a plurality of integrated circuit devices.

The additional circuit 30 may exchange signals in parallel with a plurality of devices under test 200, according to a signal from one test module 18. As a result, the additional circuit 30 can increase the number of devices under test 200 that a single test module 18 can test at the same time.

The additional circuit 30 may convert a signal received from the test module 18 into a signal with a higher clock than the received signal, for example, and supply this signal to the device under test 200. As another example, the additional circuit 30 may convert a signal received from the test module 18 into a signal with a lower clock than the received signal, and supply this signal to the device under test 200. As a result, the additional circuit 30 can test a device under test 200 that operates with a higher clock than a device that the test module 18 is capable of testing.

Each connection unit 28 is disposed on the surface of the function expanding section 24 that is not on the motherboard 22 side, i.e. the surface facing away from the test head 12. The device connecting section 26 is electrically connected to the function expanding section 24 via the connection units 28. The connection units 28 are not mechanically fixed by the connectors or the like to the device connecting section 26, and provide an electrical connection between the device connecting section 26 and the function expanding section 24. For example, the connection units 28 may include a plurality of pogo pins. In the present embodiment, the connection units 28 are fixed to the upper portion of the function expanding section 24, but may instead be fixed to the device connecting section 26, or may be fixed to neither the function expanding section 24 nor the device connecting section 26.

Since the connection units 28 are not mechanically fixed between the device connecting section 26 and the function expanding section 24, the connection apparatus 14 described above enables the device connecting section 26 to be easily exchanged. As a result, the function expanding section 24 including the additional circuit 30 can be used to test a plurality of devices under test 200, regardless of the type of the devices under test 200.

Furthermore, since the function expanding section 24 is disposed below the device connecting section 26, the connection apparatus 14 enables the additional circuit 30 to be placed relatively far from the device under test 200. As a result, the connection apparatus 14 enables the device under test 200 and the additional circuit 30 to be mechanically and thermally isolated from each other. Accordingly, with the connection apparatus 14, transmission of heat or force applied to the device under test 200 to the additional circuit 30 can be restricted. Furthermore, with the connection apparatus 14, heat generated by the additional circuit 30 and cooling for cooling the additional circuit 30 can be restricted from being transmitted to the device under test 200.

In the connection apparatus 14, the additional circuit 30 is not disposed on the top surface of the device connecting section 26. Accordingly, with the connection apparatus 14, a large number of devices under test 200 can be loaded on the top surface of the device connecting section 26, thereby enabling a large number of devices under test 200 to be tested in parallel.

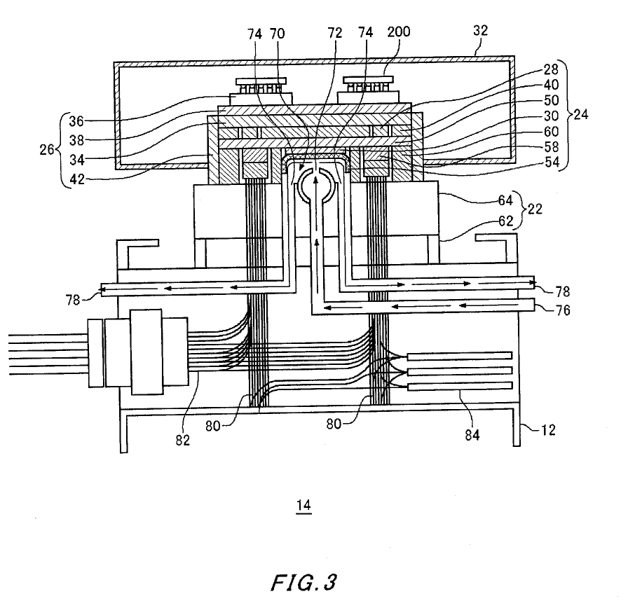

FIG. 3 shows an exemplary mechanical configuration of the connection apparatus 14 according to the present embodiment, along with devices under test 200.

The device connecting section 26 includes a socket board 34, a socket frame 38, and a side wall 42. The function expanding section 24 includes a function board 50, a connection unit 28, a connection unit frame 40, an additional circuit 30, a heat sink 54, and a function board frame 60.

The socket board 34 is a board-shaped substrate that includes a socket 36 on the top surface thereof, i.e. the surface facing away from the test head 12. The socket 36 holds the device under test 200 in a manner enabling attachment and detachment by the handler. The bottom surface of the socket board 34, i.e. the surface opposite the surface on which the socket 36 is disposed, is connected to the function board 50 via the connection units 28. The socket board 34 holds the device under test 200 and also provides an electrical connection between the function board 50 on the bottom surface thereof and the device under test 200 held by the socket 36.

The socket frame 38 surrounds a region other than the portion of the top surface of the socket board 34 where the socket 36 is disposed. The socket frame 38 may be formed by SUS, for example.

The side wall 42 surrounds the function board 50 from the sides when the socket board 34 and the function board 50 are connected. The side wall 42 may be formed of a material with low thermal conductivity, such as PEEK (polyethyl ethyl ketone) resin. The side wall 42 can prevent thermal transmission between the inside and the outside of the side wall 42.

The connection units 28 are disposed on the top surface of the function board 50, i.e. the surface facing away from the test head 12. The top surface of the function board 50 is electrically connected to the socket board 34 via the connection units 28.

The connection unit frame 40 is disposed on the top surface of the function board 50, which is the surface facing away from the test head 12. The connection unit frame 40 is shaped as a board with a thickness approximately equal to the thickness of the connection unit 28, and includes a plurality of apertures. The apertures are positioned to correspond respectively to positions where the connection units 28 are to be arranged, and each aperture is approximately the same size as the corresponding connection unit 28. The connection unit frame 40 can accurately connect terminals on the bottom surface of the socket board 34 and the terminals on the top surface of the function board 50 at corresponding positions to each other, using the connection units 28.

The connection unit frame 40 may be formed of a material with low thermal conductivity, such as a PEEK resin. The connection unit frame 40 can decrease thermal transmission between the region above the connection unit frame 40 and the region below the connection unit frame 40. The connection unit frame 40 may include, in the surface thereof contacting the function board 50, a space through which air passes. As a result, the connection unit frame 40 can further reduce the thermal transmission between the region thereabove and the region therebelow. The connection unit frame 40 can also absorb force applied to the device under test 200 by the handler or the like, thereby decreasing the force applied to the components below the connection unit frame 40.

The function board 50 includes a connector 58 on the bottom surface thereof, i.e. on the surface facing the test head 12. The connector 58 is connected to the signal cable 80, which is connected to the test module 18 in the test head 12, and to the power supply cable 82, which is connected to the power supply apparatus.

The additional circuit 30 is an integrated circuit device, and is loaded on the bottom surface of the function board 50, i.e. the surface facing the test head 12. The additional circuit 30 is connected to the test module 18 in the test head 12 via the function board 50 and the signal cable 80. The additional circuit 30 is connected to the device under test 200 via the function board 50 and the socket board 34.

The heat sink 54 is disposed on the surface of the additional circuit 30 that the function board 50 is not attached to. For example, the heat sink 54 may be a metal cylinder with one closed end, and the outer surface of the closed end may be attached to the additional circuit 30. This heat sink 54 can dissipate heat generated by the additional circuit 30, and can form a cooling chamber 70 having a substantially sealed space within the cylinder.

The function board frame 60 is disposed on the bottom surface of the function board 50, i.e. the surface facing the test head 12. The function board frame 60 is shaped as a board with apertures formed at the positions corresponding to the additional circuit 30 and the connector 58. The function board frame 60 holds the function board 50 and mechanically connects the function board 50 to the motherboard 22.

The motherboard 22 includes a motherboard frame 62, a support section 64, and a connector guiding section 66. The motherboard frame 62 is loaded on the test head 12 and holds components that are disposed within the motherboard 22. The support section 64 is disposed on the motherboard frame 62 and supports the function expanding section 24. For example, the support section 64 fixes and supports the function board frame 60 of the function expanding section 24 from below.

The motherboard 22 includes an injecting section 72, an exhaust section 74, an injection path 76, and an exhaust path 78. The injecting section 72 emits gas toward the function board 50 from the test head 12 side to cool the additional circuit 30. In the present embodiment, the injecting section 72 emits gas into the space within the cooling chamber 70 formed by the heat sink 54. The exhaust section 74 expels the gas from the space in the cooling chamber 70 formed by the heat sink 54.

The injection path 76 is a path for sending gas output from an external heat exchanger to the injecting section 72. The exhaust path 78 is a path for returning the gas expelled from the exhaust section 74 to the external heat exchanger.

The injecting section 72 and the exhaust section 74 can cool the additional circuit 30 via the heat sink 54. The heat sink 54 forms the cooling chamber 70 having the sealed space therein, and therefore the additional circuit 30 can be efficiently cooled without cooling gas leaking to the outside. The gas circulated within the space in the cooling chamber 70 is preferably compressed dry air. In this way, condensation is prevented in the cooling chamber 70 when the temperature is low.

The motherboard 22 includes the signal cable 80, the power supply cable 82, and a sub-board 84. The signal cable 80 provides a connection between the test module 18 in the test head 12 and the function board 50. The signal cable 80 may be a coaxial cable, for example. The power cable 82 may provide a connection between an external power supply apparatus and the function board 50. The sub-board 84 is disposed within the motherboard 22, between the function board 50 and the test module 18 of the test head 12.

The connection apparatus 14 may have a chamber 32 mounted thereon by the handler or the like when testing a device. The chamber 32 encloses the devices under test 200 so that the atmosphere around the devices under test 200 can be controlled to have a predetermined temperature and humidity. As a result, the test apparatus 10 can perform quick and reliable testing of devices under test 200.

The connection apparatus 14 of the present embodiment has the function board 50 disposed on the bottom surface of the socket board 34 and has the additional circuit 30 disposed on the surface of the function board 50 facing the test head 12. Therefore, the connection apparatus 14 can prevent heat added to the device under test 200 from affecting the additional circuit 30, and can prevent the device under test 200 from being affected by heating or cooling of the additional circuit 30. Furthermore, the connection apparatus 14 can decrease the mechanical stress placed on the additional circuit 30 when the devices under test 200 are attached, for example.

The connection apparatus 14 includes the socket frame 38, the connection unit frame 40, and the side wall 42. Accordingly, the connection apparatus 14 can thermally isolate the space within the chamber 32 and the additional circuit 30 from each other.

In the connection apparatus 14, the additional circuit 30 is not disposed on the top surface of the socket board 34. Accordingly, with the connection apparatus 14, a large number of devices under test 200 can be attached to the top surface of the socket board 34, thereby enabling a large number of devices under test 200 to be tested in parallel.

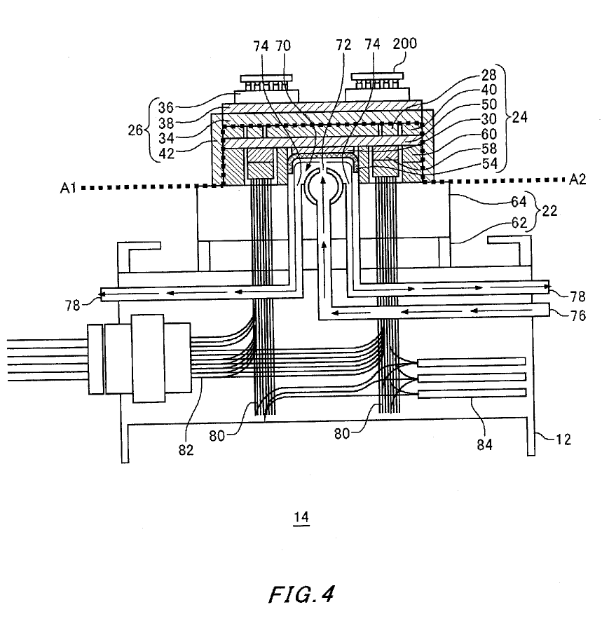

FIG. 4 shows an exemplary mechanical structure of the connection apparatus 14 according to the present embodiment, along with a line indicating a portion that is exchanged together with replaceable parts of the device under test 200.

The connection apparatus 14 electrically connects the socket board 34 to the function board 50, but the socket board 34 and the function board 50 are not mechanically fixed by connectors or the like. Accordingly, during maintenance or the like, the connection apparatus 14 enables the socket board 34 to be easily detached from the function board 50. The portion of the connection apparatus 14 above the dotted line A1-A2 in FIG. 4 may be removed, for example.

Accordingly, the connection apparatus 14 enables the function board 50 and the additional circuit 30 to be shared regardless of the type of the device under test 200. As a result, the connection apparatus 14 can decrease the cost of testing.

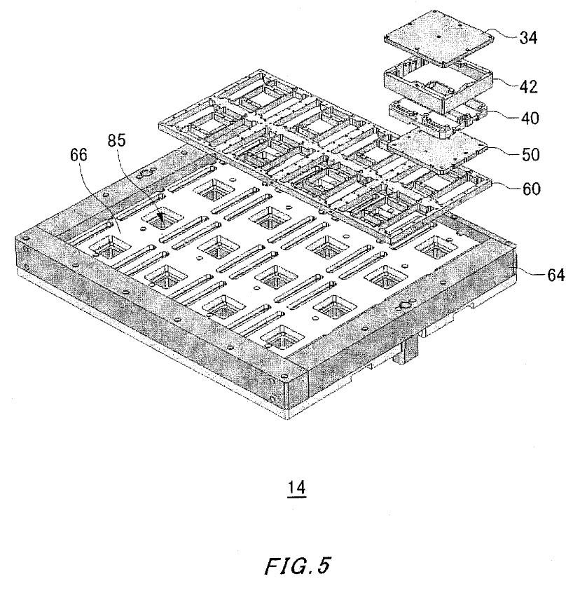

FIG. 5 shows a partial structure of the connection apparatus 14 according to the present embodiment. The socket board 34 may be a thin board with a substantially square planar shape, for example. The socket 36 and the socket frame 38, which are not shown in FIG. 5, are disposed on the socket board 34.

The function board 50 is a thin board that is slightly smaller than the socket board 34, and has a planar shape resembling that of the socket board 34. The additional circuit 30 with the heat sink 54 attached thereto is disposed on the surface of the function board 50 that the socket board 34 is not connected to.

The connection unit frame 40 is sandwiched between the function board 50 and the socket board 34. The connection unit frame 40 is a board whose planar shape substantially matches that of the function board 50. The connection unit frame 40 may be thicker than the function board 50 and the socket board 34, and may have an aperture through which the connection unit 28 is inserted formed at a predetermined position in the planar surface thereof. The connection unit frame 40 has a groove formed in the surface thereof that contacts the function board 50, enabling air to pass therethrough. The connection unit frame 40 prevents thermal transmission between the socket board 34 and the function board 50.

The side wall 42 is a cylinder with an inner circumference whose planar shape matches that of the function board 50 and the connection unit frame 40 and with an output circumference whose planar shape substantially matches that of the socket board 34. The side wall 42 prevents thermal transmission between (i) the function board 50 and the additional circuit 30 and (ii) the atmosphere around the device under test 200.

The function board frame 60 supports the pair of the function board 50 and the socket board 34 from below. In the example of FIG. 5, the function board frame 60 supports eight pairs of a function board 50 and a socket board 34.

The support section 64 is a square frame having apertures formed therein, and is provided in the upper portion of the motherboard 22. The support section 64 supports one or more function board frames 60. In the example of FIG. 5, the support section 64 supports two function board frames 60.

The support section 64 includes a connector guiding section 66 therein. The connector guiding section 66 holds the power supply cable 82 and the signal cable 80 connected to the function board 50. The support section 64 includes holes 85 in which components are arranged for the injection or expelling of cooling gas, and these holes 85 are arranged at positions corresponding respectively to additional circuits 30 disposed on respective function boards 50.

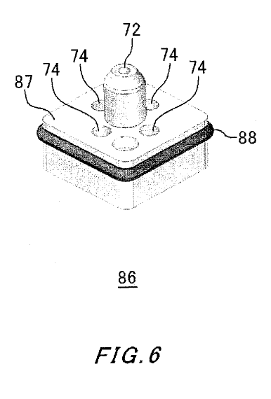

FIG. 6 shows an exemplary component for injecting and expelling cooling gas according to the present embodiment. As shown in FIG. 6, the component for injecting and expelling cooling gas to and from the additional circuit 30 may be a nozzle 86. The nozzle 86 includes a base 87, an injecting section 72, and an exhaust section 74. The nozzle 86 includes an annular packing 88 attached to the sides of the base 87. A nozzle 86 such as this is attached in each of the holes 85 shown in FIG. 5.

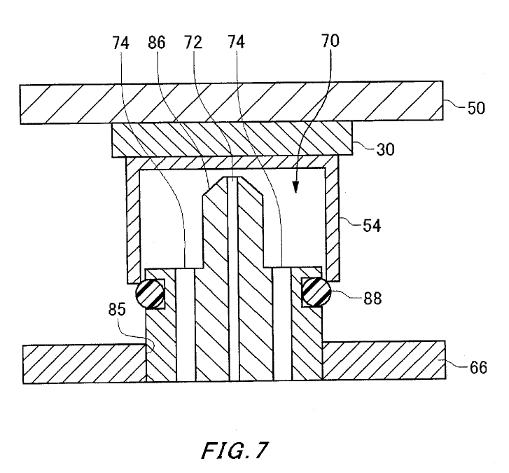

FIG. 7 shows an exemplary connection of a component for injecting and expelling cooling gas according to the present embodiment. The outer circumference of the base 87 of the nozzle 86 has a shape that is substantially the same as that of the open portion of the heat sink 54 formed as a cylinder.

When the function board frame 60 on which the function board 50 is disposed is loaded in the connector guiding section 66, the end of the open portion of the heat sink 54 contacts the annular packing 88. As a result, the heat sink 54 and the nozzle 86 can form the cooling chamber 70 containing a sealed space.

The injecting section 72 formed in the nozzle 86 can inject cooling gas into the space within the cooling chamber 70. The exhaust section 74 formed in the nozzle 86 can expel gas from the space within the cooling chamber 70. For example, the injecting section 72 may inject the gas from a position closer to the additional circuit 30 than the exhaust section 74. As a result, the injecting section 72 and the exhaust section 74 can efficiently circulate the gas heated by the additional circuit 30.

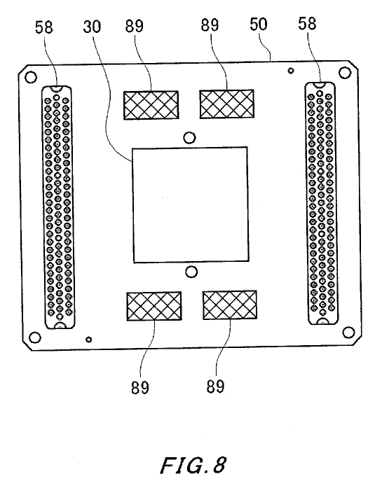

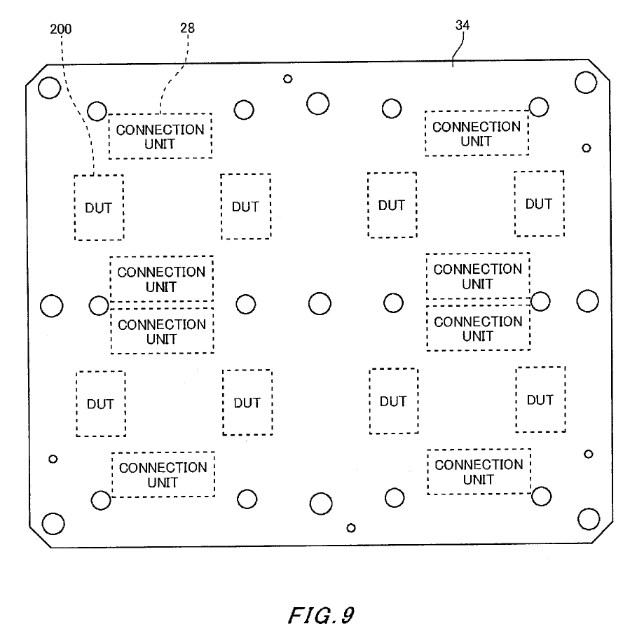

FIG. 8 shows an exemplary bottom surface of the function board 50, i.e. the surface facing the test head 12, according to the present embodiment. FIG. 9 shows an exemplary arrangement of connection units 28 and devices under test 200 connected to the socket board 34, according to the present embodiment.

As shown in FIG. 8, connectors 58, one additional circuit 30, and DC-DC conversion circuits 89 are disposed on the bottom surface of the function board 50 of the present embodiment. The connectors 58 may be LIF (Low Insertion Force) connectors that connect a plurality of coaxial signal lines. The DC-DC conversion circuits 89 increase or decrease the DC voltage supplied from the power supply apparatus to convert this DC voltage to a power supply voltage for the devices under test 200.

As shown in FIG. 9, a plurality of devices under test 200 may be disposed on the socket board 34. In the present embodiment, eight devices under test 200 are disposed on the socket board 34. A plurality of connection units 28 are connected to the socket board 34. Each connection unit 28 has the same configuration. In the present embodiment, eight connection units 28 are respectively connected to the eight devices under test 200.

By using the socket board 34 and the function board 50 shown in FIGS. 8 and 9, the connection apparatus 14 enables a plurality of devices under test 200 to be equipped in correspondence with a single additional circuit 30. As a result, the test apparatus 10 according to the present embodiment can test a plurality of devices under test 200 in parallel using a single additional circuit 30.

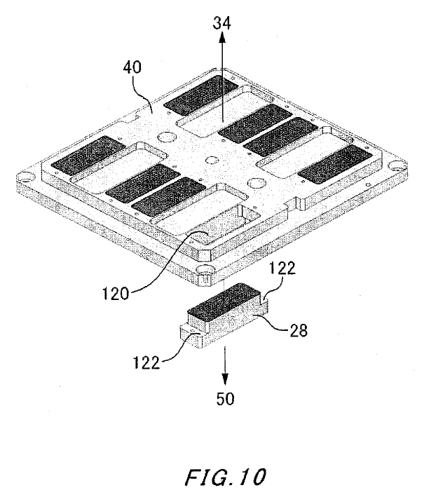

FIG. 10 shows an exemplary connection unit 28 and connection unit frame 40 according to the present embodiment. The connection unit 28 may be a component obtained by forming a plurality of pins integrally using a resin or the like. In the connection unit 28, the tips of each pin are exposed on both the surface facing the socket board 34 and the surface facing the function board 50.

The connection unit frame 40 includes a plurality of apertures 120 that each have substantially the same shape as a corresponding connection unit 28 and that are arranged at positions corresponding to the connection units 28. When inserted in the corresponding aperture 120, each connection unit 28 is fixed by being sandwiched between the socket board 34 and the function board 50. As a result, each connection unit 28 can provide an electrical connection between a terminal provided at a predetermined position on the socket board 34 and a terminal provided at a predetermined position on the function board 50.

The connection units 28 may be inserted to the connection unit frame 40 from the function board 50 side, for example. Each connection unit 28 has an engaging member 122 that protrudes to contact a portion of the connection unit frame 40 when the connection unit 28 is inserted to the connection unit frame 40. With the connection unit frame 40 and connection units 28 described above, the connection units 28 are prevented from passing through the connection unit frame 40 during insertion.

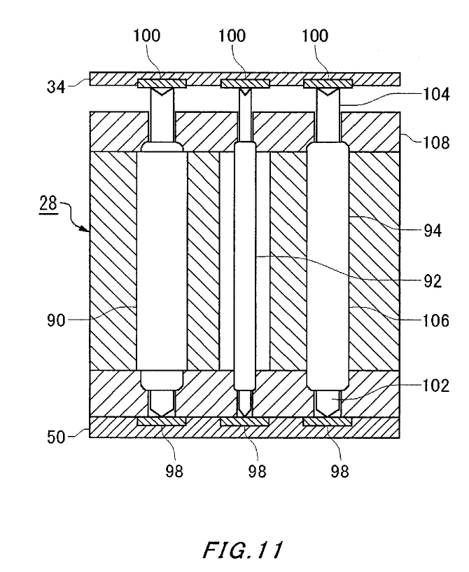

FIG. 11 shows an exemplary internal configuration of a connection unit 28 according to the present embodiment. The connection unit 28 may have a plurality of pins including a power supply pin 90, a signal pin 92, and a ground pin 94. The power supply pin 90, the signal pin 92, and the ground pin 94 each include a function-board-side probe 102, a socket-board-side probe 104, and a probe connecting section 106.

Each function-board-side probe 102 is a metal probe exposed to the outside from the surface of the connection unit 28 facing the function board 50. Each function-board-side probe 102 contacts a terminal pad 98 of the function board 50 when the socket board 34 is connected to the function board 50.

Each socket-board-side probe 104 is a metal probe exposed to the outside from the surface of the connection unit 28 facing the socket board 34. Each socket-board-side probe 104 contacts a terminal pad 100 of the socket board 34 when the socket board 34 is connected to the function board 50.

Each probe connecting section 106 holds the corresponding function-board-side probe 102 in a manner to allow movement in the axial direction, and achieves this holding by applying an outward force using a spring or the like. Furthermore, each probe connecting section 106 holds the corresponding socket-board-side probe 104 in a manner to allow movement in the axial direction, and achieves this holding by applying an outward force using a spring or the like. Each probe connecting section 106 provides an electrical connection between the corresponding function-board-side probe 102 and socket-board-side probe 104.

The connection unit 28 includes fixing portions 108 that fixes the integrated power supply pin 90, signal pin 92, and ground pin 94 at predetermined locations. The fixing portions 108 hold each of the power supply pin 90, the signal pin 92, and the ground pin 94 via the ends of the probe connecting section 106 on the function board 50 side and the socket board 34 side. The fixing portions 108 may be a resin, for example.

The power supply pin 90 connects to a power supply line. Accordingly, the power supply pin 90 preferably has a thicker transmission line than the signal pin 92. The probe connecting section 106 of the power supply pin 90 is preferably covered by an insulating material or the like. The ground pin 94 connects to a ground line. Accordingly, the ground pin 94 preferably has a thicker transmission line than the signal pin 92.

In the connection unit 28 having the above configuration, the device connecting section 26 and the function expanding section 24 are electrically connected to each other without being mechanically fixed by connectors or the like.

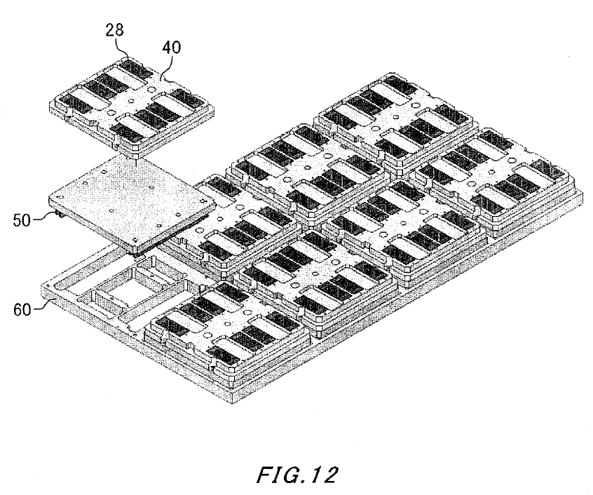

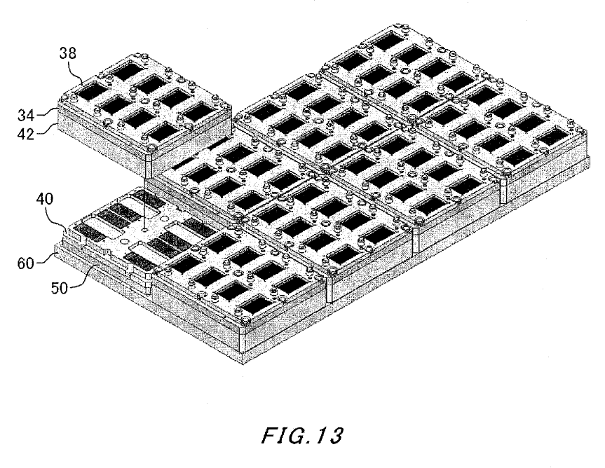

FIG. 12 shows an exemplary connection of the function board 50, the connection unit 28, and the connection unit frame 40 in the function board frame 60 according to the present embodiment. FIG. 13 shows an exemplary connection of the function board 50, the connection unit frame 40, the side wall 42, the socket board 34, and the socket frame 38 in the function board frame 60 according to the present embodiment.

As shown in FIG. 12, the connection unit 28 may be inserted in the connection unit frame 40 and attached to the function board 50. The function board 50 with the connection unit frame 40 and the connection unit 28 attached thereto is disposed at a corresponding position on the function board frame 60.

As shown in FIG. 13, a unit obtained by integrally forming the side wall 42, the socket board 34, and the socket frame 38 is attached to the function board frame 60 on which the connection unit frame 40 and the function board 50 are disposed. Since each unit is integrally formed, the connection apparatus 14 described above enables easy manufacturing and maintenance.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that is connected to a socket board corresponding to a type of device under test and tests the device under test, the test apparatus comprising:
a test head including therein a test module that tests the device under test;
a function board that is connected to the test module in the test head via a cable and also connected to the socket board; and
an additional circuit that is loaded on the function board and connected to the test module and the device under test.

2. The test apparatus according to claim 1, wherein
the additional circuit is an integrated circuit device that is connected to the test module and the device under test, and is controlled by the test module to test the device under test.

3. The test apparatus according to claim 1, wherein
the function board includes, on a surface thereof facing the test head, a connector that connects to the cable connecting the function board to the test module, and a surface of the function board facing away from the test head is connected to the socket board, and
the additional circuit is loaded on the surface of the function board facing the test head.

4. The test apparatus according to claim 1, wherein
the function board and the additional circuit can be used in common by a plurality of devices under test, regardless of the type of the devices under test.

5. The test apparatus according to claim 3, further comprising an injecting section that injects gas from a test head side of the function board to cool the additional circuit.

6. The test apparatus according to claim 5, further comprising:
a cooling chamber that has a sealed space and is disposed on the additional circuit; and
an exhaust section that expels gas from the space in the cooling chamber, wherein
the injecting section injects the gas into the space in the cooling chamber.

7. The test apparatus according to claim 6, further comprising:
a function board frame that is disposed on the surface of the function board facing the test head and includes apertures at positions of the additional circuit and the connector; and
a side wall that surrounds the additional circuit from sides of the function board.

8. The test apparatus according to claim 1, further comprising a connection unit that is inserted between the function board and the socket board and provides an electrical connection between a terminal of the function board and a terminal of the socket board.

9. The test apparatus according to claim 8, wherein
the connection unit provides an electrical connection between a plurality of terminals of the function board and a plurality of terminals of the socket board, and
the function board and the socket board are connected to each other by a plurality of the connection units having the same configuration.

10. The test apparatus according to claim 9, further comprising a connection unit frame that is sandwiched between the function board and the socket board and that includes apertures formed at positions where the connection units are to be arranged.

11. The test apparatus according to claim 10, wherein
each connection unit has an engaging member that engages with a portion of the connection unit frame when the connection unit is inserted in the connection unit frame.

12. A connection apparatus that is loaded on a test head having therein a test module for testing a device under test, the connection apparatus comprising:
a function board that is connected to the test module in the test head via a cable and also connected to a socket board corresponding to a type of the device under test; and
an additional circuit that is loaded on the function board and connected to the test module and the device under test.

13. The connection apparatus according to claim 12, further comprising:
a function board frame that is disposed on a surface of the function board facing the test head and includes apertures at positions of the additional circuit and a connector connected to the cable connecting the function board to the test module; and
a side wall that surrounds the additional circuit from sides of the function board.
